(19) United States
(12) Patent Application Publication
(10) Pub. No.: US 2014/0036426 A1
(43) Pub. Date: Feb. 6, 2014

(54) ELECTRONIC APPARATUS

(71) Applicant: Nandanahosur Sahadevappa Suresh, Singapore (SG)

(72) Inventor: Nandanahosur Sahadevappa Suresh, Singapore (SG)

(73) Assignee: TP VISION HOLDING B.V., AMSTERDAM (NL)

(21) Appl. No.: 13/983,444

(22) PCT Filed: Jan. 27, 2012
(86) PCT No.: PCT/IB2012/050397

§ 371 Date: Oct. 21, 2013

(30) Foreign Application Priority Data
Feb. 3, 2011 (EP) 11153159.6

(51) Int. Cl. H05K 5/02

(52) U.S. Cl. CPC H05K 5/0221
USPC 361/679.01

(57) ABSTRACT

An electronic apparatus 1 is provided with a structure 3 and a cover 7 for covering the structure. The apparatus 1 is further provided with a mounting device 9 for detachably mounting the cover 7 to the structure 3, wherein attaching the cover 7 as well as detaching the cover 7 can be take place in an easy way. The mounting device 9 comprises a first mounting portion 9A and a second mounting portion, which portions are constituted for mutual cooperation. One of the mounting portions 9A is connected to the structure and the other mounting portion is connected to the cover 7. The second mounting portion is stationarily arranged and the first mounting portion 9A is movably arranged between a lock position and an unlock position. In the lock position the first and second mounting portions are engaged for retaining the cover 7 in its mounting position. In the unlock position the first and second mounting portions are released.

### FIELD OF THE INVENTION

The invention relates to an electronic apparatus provided with a structure, a cover for at least partially covering the structure and a means for detachably mounting the cover to the structure. Such an electronic apparatus may be any kind of electronic apparatus, such as consumer electronics (CE) apparatus for audio and/or video purposes and display apparatus, more particularly panel display apparatus.

### BACKGROUND OF THE INVENTION

Electronic apparatus are provided with a structure supporting electric and/or electronic means and/or electric circuits and are usually provided with a cover means for providing protection of said means and circuits against external influences and protection against direct contact. Such a cover means may include housing, a case or an enclosure and is usually provided with a detachable cover. The detachable cover is usually a rear cover and serves for making the apparatus accessible for maintenance and repair purposes. A known solution for mounting a rear cover makes use of a front cover provided with catches and slots provided along the periphery of the rear cover. In the mounted position of the rear cover said catches are caught into the slots for holding the rear cover in place. This known solution has the drawback that detaching the rear cover from the front cover is difficult and requires special care to press the catches out of the slots to prevent damaging one or both covers. Particularly in case of plastic covers the risk of deforming or defacing a finishing coat is considerable.

### SUMMARY OF THE INVENTION

It is an object of the invention to provide an efficient solution to the above problem. More particularly, it is an object to provide an electronic apparatus of which a cover can be attached and/or detached in a simple manner.

This object is achieved by the electronic apparatus as described in claim 1. More particularly, the electronic apparatus according to the invention is provided with a structure, a cover for at least partially covering the structure and a mounting device for detachably mounting the cover to the structure, which mounting device comprises a first mounting portion and a second mounting portion, which portions are constituted for mutual cooperation, wherein one of the mounting portions is connected to the structure and the other mounting portion is connected to the cover, wherein the second mounting portion is stationarily arranged and the first mounting portion is movably arranged with respect to the structure and the cover between a lock position and an unlock position, in which lock position the first and second mounting portions are engaged for retaining the cover in its mounting position, and in which unlock position the first and second mounting portions are released. For the sake of clarity it is noted that the second mounting portion is stationarily arranged with respect to at least the cover or the structure, depending on the part, i.e. the cover or the structure, it is connected to. In said lock position the second mounting portion is even stationarily arranged with respect to the structure and the cover. By making use of a mounting device which comprises mutually movable mounting portions attaching the cover to the structure as well as detaching the cover to the structure takes place in a smooth way, thereby limiting the risk of damaging any part of the apparatus during any action of attaching and detaching the cover. In the lock position the first and second mounting portions are engaged for mounting the cover in its mounting position. In the unlock position the first and second mounting portions are released. In this position the cover can be removed from its mounting position. Moreover, in case the cover is not in its mounting position, the cover can be brought from a remote position to its mounting position in the unlock position. It is noted that the term structure may be any mechanical construction or assembly of the apparatus to which the cover is mounted in its mounting position or is mountable if the cover is detached or is not yet mounted.

A preferred embodiment of the apparatus according to the invention is characterized in that the mounting device is substantially situated between the structure and the cover. This embodiment has the advantage that the cover is hold in place without any or at least hardly any mounting component visible from the outside. Due to this feature the appearance of the cover is not negatively influenced by its mounting technology. In this context it is noted that a conventional solution for mounting a rear cover makes use of external screws which are screwed through the cover into screw holes in the structure, Generally, a large number of screws are needed. A drawback of this conventional solution is the visibility of the screws from the outside. Particularly in nowadays consumer electronics products, but also in other electronic products, aesthetic requirements are rather high. For this reason hiding covers are sometimes placed over the screwed covers to hide the screws.

Although the first mounting part can in principle be configured for making movements of any kind, e.g. rotational movements, a preferred embodiment of the apparatus according to the invention is characterized in that the first mounting portion is slideably arranged, i.e. is arranged with respect to the structure and the cover in a slideable way. Such a way requires only simple mechanical provisions to perform the required actions, i.e. to move the first mounting part between the lock and unlock position.

A preferred embodiment of the apparatus according to the invention is characterized in that the mounting device is provided with a holder in which the first mounting portion is movably arranged. In this embodiment the holder and the first mounting part constitute a constructional unit, of which the holder is the stationary part and the first mounting part is the movable part. In this embodiment the first mounting part is beared in or by the holder resulting in a reliable unit and therefore in well-defined movements of the first mounting portion.

A preferred embodiment of the apparatus according to the invention is characterized in that the first mounting portion is connected to the structure and the second mounting portion is connected to the cover, whereby the second mounting portion is stationarily arranged with respect to at least the cover. By these features the thickness dimension and/or the stability of the cover is not influenced by the movable portion of the mounting device. Particularly in embodiments wherein the first mounting portion is arranged in the holder, it is favorable to secure the holder to the structure instead of securing the holder to the cover. The holder as well as the first mounting portion may be manufactured from any suitable metal, e.g. aluminum or zinc-coated steel, or plastics. The cover as well as the second mounting portion may also be manufactured from any suitable metal or plastics. The cover will usually be made from plastics, such as polycarbonate and acrylonitrile butadiene styrene polymer (PC/ABS), acrylonitrile butadiene styrene polymer (ABS), high impact polystyrene (HIPS), high impact polystyrene polyphenylene oxide (HIPS PPO). In case of a plastic cover, the second mounting portion is preferably an integral part of the cover, wherein the cover and the second portion are formed e.g. by injection molding. In case of a metal cover, the second mounting portion is an additional part which is fixed to the cover by e.g. mechanical means, like a soldered joint, a glue joint, a double-sided tape connection.

A preferred embodiment of the apparatus according to the invention is characterized in that the first mounting portion is provided with a carrier provided with at least two first lock elements and the second mounting portion is provided with at least two second lock elements, wherein the first and second lock elements are pairwisely interlocked in the lock position. In the lock position the first and second lock elements are interlocked in a pairwise way, i.e. at least two pairs of an interlocked first lock element and second lock element are constituted. Depending on e.g. the dimensions and/or the material of the cover, the cover has to be fixed to the structure at a certain number of fixing locations. In this embodiment accomplishing fixations at two or more, e.g. three, four or five, fixing locations can be realized by one movement of the carrier. The same applies for undoing the fixations. By the measures applied into the present embodiment mounting as well as removing the cover can be performed by a few actions, resulting in a considerable reduction of costs during both the manufacturing process and maintenance and/or repair operations.

A preferred embodiment of the apparatus according to the invention is characterized in that the carrier is provided with a control element for controlling its movements. As already mentioned in a foregoing paragraph the mounting device is preferably located between the structure and the cover in order to be hided from the outside. In such case the carrier is also situated between the structure and the cover. The provision of the control element, which may be an end portion of the carrier, enables an easy operation of the carrier. Preferably, the control element is provided near an outline of the cover in view of accessibility.

A practical embodiment of the apparatus according to the invention is characterized in that the first lock elements and/or the second lock elements are constituted as catch elements. Both lock elements may be shaped as catches, e.g. in the form of hooks or hook-like elements. Alternatively, only the first lock elements or the second lock elements may be constituted as catch elements, while the other lock elements may be openings, recesses and the like, configured for receiving the catch elements.

A preferred embodiment of the apparatus according to the invention is characterized in that the carrier is a slider. The slider is provided with at least two first lock elements and the second mounting portion is provided with at least two second lock elements, wherein the first and second lock elements are pairwisely interlocked in the lock position. In the lock position the first and second lock elements are interlocked in a pairwise way, i.e. at least two pairs of an interlocked first lock element and second lock element are constituted. Depending on e.g. the dimensions and/or the material of the cover, the cover has to be fixed to the structure at a certain number of fixing locations. In this embodiment accomplishing fixations at two or more, e.g. three, four or five, fixing locations can be realized by one linear movement of the slider. The same applies for undoing the fixations. By the measures applied into the present embodiment mounting as well as removing the cover can be performed by a few actions, resulting in a considerable reduction of process time and thus costs during both the manufacturing process and maintenance and/or repair operations. In case the mounting device is provided with the holder, the slider may be slideably beared by or in the holder. Such an embodiment is preferred. An embodiment in which the slider is provided with the control element is also preferred. As the mounting device is preferably located between the structure and the cover in order to be hided from the outside, the slider is also situated between the structure and the cover. The provision of the control element, which may be an end portion of the slider, enables an easy operation of the slider. Preferably, the control element is provided near an outline of the cover in view of accessibility.

A preferred embodiment of the apparatus according to the invention is characterized in that at least two mounting devices provided with the carrier, particularly the slider, are provided, which mounting devices are located at a distance from each other. By this characterizing feature a stable fixation of the cover to the structure is warranted. Preferably, the at least two mounting devices extends along circumferential edge portions of the cover. In principle these edge portions may be any circumferential edge portions of the cover. In case of just two edge portions, the edge portions are preferably two parallel edge portions, preferably two vertically oriented edge portions, considered in the customary operational position of the apparatus. In the present embodiment the cover can be locked as well as unlocked by a simple operation of the carrier. In case the carrier is constituted as a slider, the operation is reduced to restricted linear movements.

A preferred embodiment of the apparatus according to the invention is provided with a housing, wherein the cover is a part of the housing.

A preferred embodiment of the apparatus according to the invention is characterized in that the housing is provided with a front portion and a rear portion, wherein the rear portion is constituted by the cover.

A preferred embodiment of the apparatus according to the invention is a flat-panel display apparatus. In this embodiment the structure comprises a flat-panel display. This implies that the invention also relates to a flat-panel display apparatus provided with a structure equipped with a flat-panel display, a cover for at least partially covering the structure and a mounting device for detachably mounting the cover to the structure, which mounting device comprises a first mounting portion and a second mounting portion, which portions are constituted for mutual cooperation, wherein one of the mounting portions is connected to the structure and the other mounting portion is connected to the cover, wherein the second mounting portion is stationarily arranged and the first mounting portion is movably arranged between a lock position and an unlock position, in which lock position the first and second mounting portions are engaged for mounting the cover in its mounting position, and in which unlock position the first and second mounting portions are released. All the embodiments described in the foregoing are also embodiments of the panel display apparatus according to the invention. All benefits relating to the electronic apparatus according to the invention and its embodiments described in the foregoing are also benefits relating to the panel display apparatus according to the invention and its embodiments, respectively. It is noted that the flat-panel display apparatus may be of any available or new type of flat-panel display apparatus, such as a liquid crystal display (LCD) apparatus, a plasma display apparatus, an organic light-emitting diode display (OLED) apparatus, a light-emitting diode display (LED) apparatus, an electroluminescent display (ELD) apparatus, a surface-conduction electron-emitter display (SED) apparatus and a field emission display (FED) apparatus, also called a nano-emissive display (NED) apparatus. The flat-panel display apparatus according to the invention may be a TV set and/or a monitor. The styling of a consumer electronics product is one of the key issues for customers to select a certain apparatus and to decline other apparatus. More particularly, customers of today prefer an apparatus having a modern outlook. For this reason manufacturers in the field of consumer electronics (CE) strive for designing housings having smooth outer surfaces, i.e. housings without visible awkward mounting screws or other fasteners and without awkward seams between housing parts. The flat-panel display apparatus, and more in general the electronic apparatus, according to the invention meets these aesthetic requirements.

The invention also relates to a use of the apparatus according to the invention.

With reference to the attached claims it is explicitly noted that all possible combinations of features mentioned in the claims are part of the invention.

### BRIEF DESCRIPTION OF THE DRAWINGS

A detailed description of the invention is provided below. The description is provided by way of non-limiting examples to be read with reference to the drawings in which:

FIG. 1 shows in an exploded and perspective view an embodiment of the electronic apparatus, more particularly the panel display apparatus, according to the invention, which apparatus is provided with structure, a cover and two mounting devices each comprising a first mounting portion and a second mounting portion;

FIG. 2 shows in a an exploded and perspective view the embodiment shown in FIG. 1, however without the cover;

FIG. 3 shows in a rear view the embodiment shown in FIG. 1, however without the cover and in another condition;

FIG. 4 shows in an perspective view an embodiment of the first mounting portion and a holder for it;

FIG. 5A shows a detail of the embodiment of the first mounting portion shown in FIG. 4, wherein the first mounting portion is in its lock position;

FIG. 5B shows the detail as shown in FIG. 5A, wherein the first mounting portion however is in its unlock position;

FIG. 6A shows in a top view the detail as shown in FIG. 5B, wherein the holder is secured to the structure;

FIG. 6B shows in a perspective view the detail as shown in FIG. 6A;

FIG. 7A shows in a top view the detail as shown in FIG. 5A, wherein the holder is secured to the structure;

FIG. 7B shows in a perspective view the detail as shown in FIG. 7A;

FIG. 8 shows in a view directed to the interior side of the cover, an embodiment of the second mounting portion;

FIG. 9 shows in a perspective view a detail of the embodiment of the second mounting portion shown in FIG. 8;

FIG. 10A shows in a perspective view a detail of the mounting device in a lock position; and

FIG. 10B shows in a perspective view a detail of the mounting device in an unlock position.

### DETAILED DESCRIPTION OF THE EMBODIMENTS

It is expressly noted that the disclosed embodiments are schematically depicted. The embodiments relate to examples of the apparatus according to the invention.

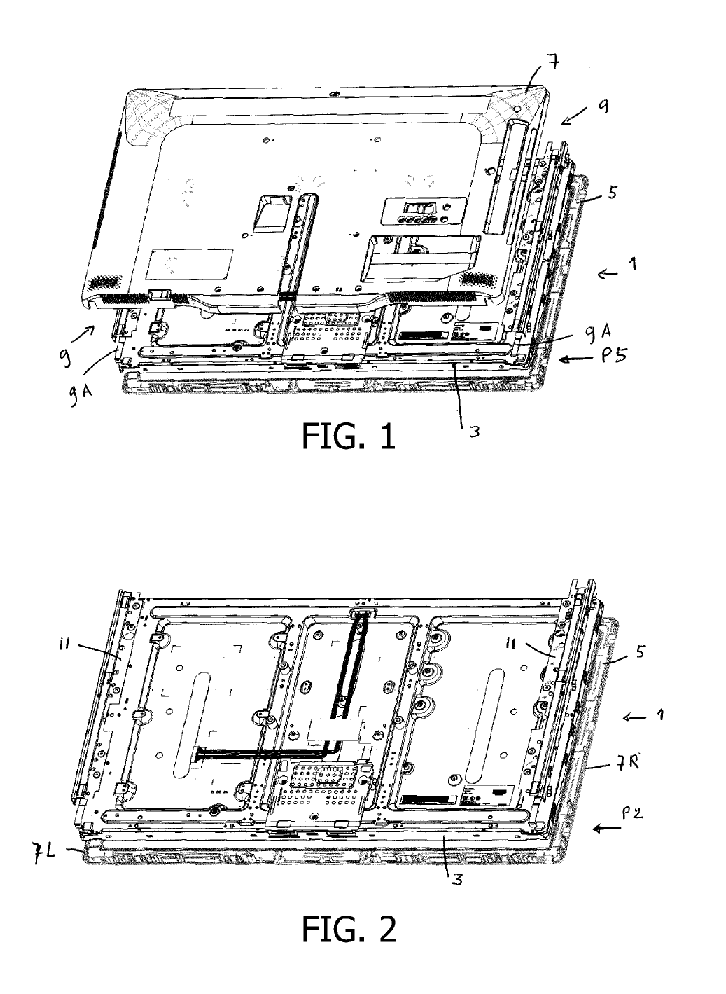

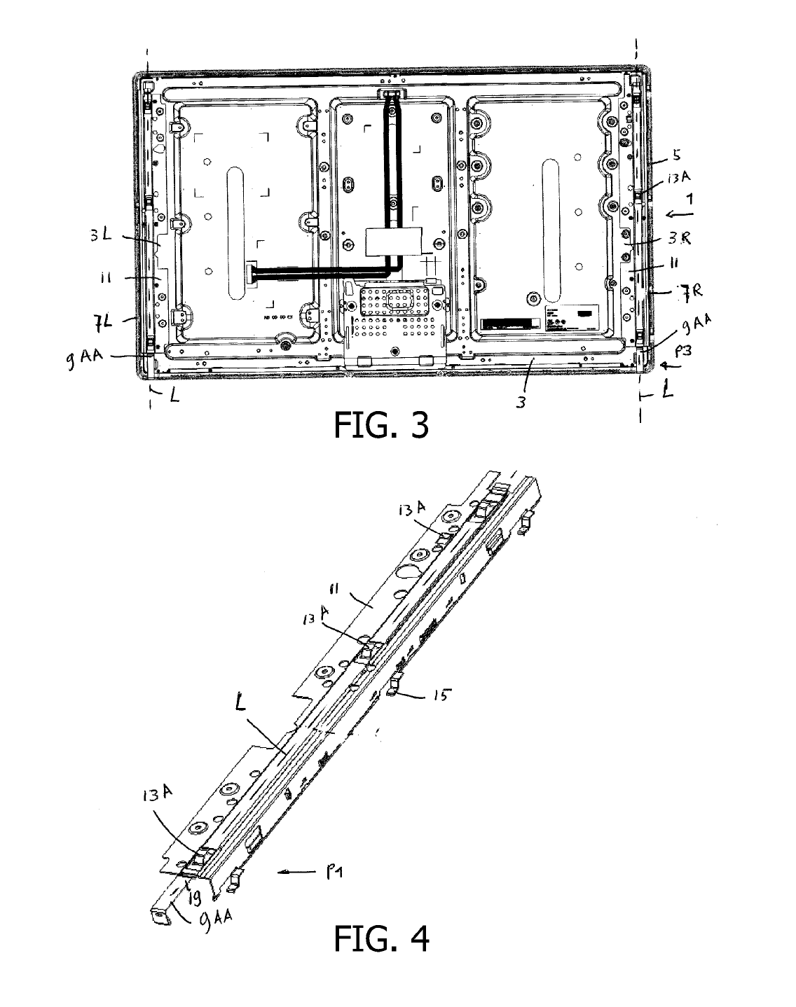

The flat-panel display apparatus 1 as illustrated in the FIG. 1 and partly in the FIGS. 2 and 3 represents a LCD/LED TV apparatus in this example, but it may be any kind of consumer electronics (CE) products. The apparatus 1 is provided with a structure 3, being a thin flat-panel construction or a structure provided with a flat-panel display unit, and is further provided with a front cover 5 and a rear cover 7. The rear cover 7 is also simply mentioned a cover or the cover in this patent document. The front cover 5 and the rear cover 7 form together a housing 5, 7. Flat-panel constructions and flat-panel display units are known per se and for this reason will not be further discussed here. The front cover 5 surrounds a screen and is fastened to the structure 3 in a conventional way, e.g. by means of screws located in areas not visible from the outside. The rear cover 7 is meant for covering the rear side of the assembly constituted by the structure 3 and the front cover 5.

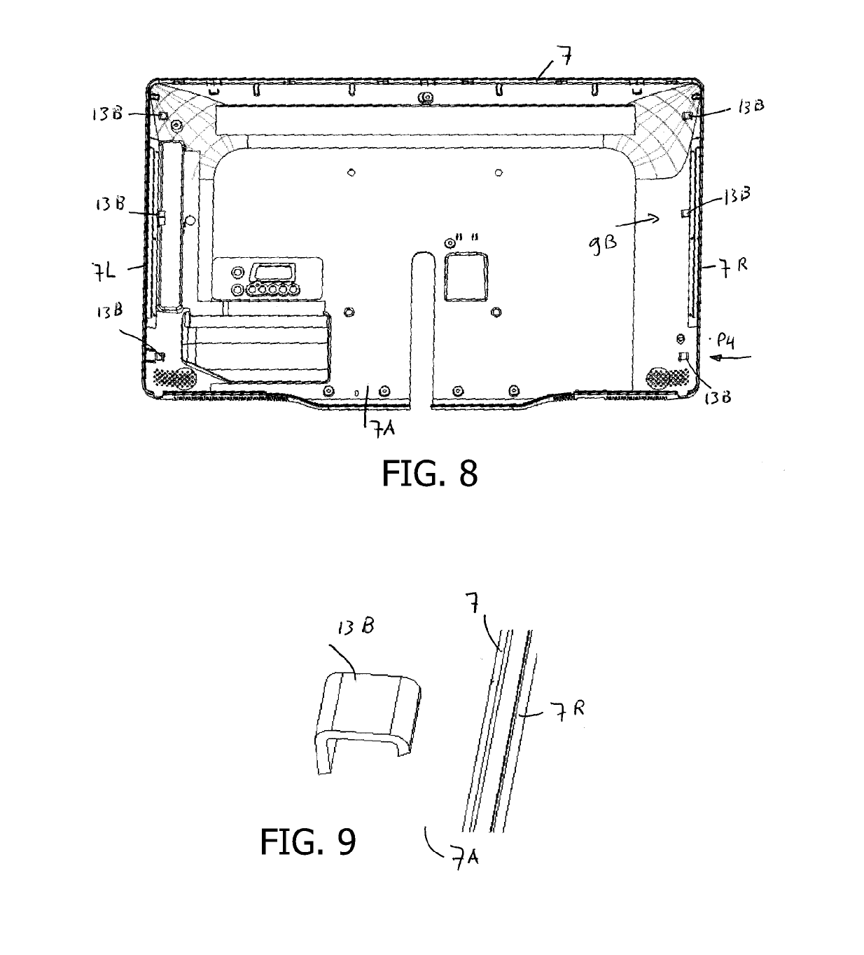

The apparatus 1 is provided with two mounting devices 9 for detachably mounting the rear cover 7 to the structure 3, and is provided with two holders 11. The holders 11 are fixed to the structure 3, in this example by means of click or catch bodies 15—see e.g. FIG. 4—and screws, if any. Each mounting device 9 comprises a first mounting portion 9A and a second mounting portion 9B—see FIG. 8—which portions 9A, 9B are constituted for mutual cooperation. The first mounting portion 9A is connected to the structure 3 and the second mounting portion 3B is connected to the rear cover 7. More in particular, the first mounting portion 9A is provided with a slideable carrier, further indicated as the slider 9 AA, which is slideably arranged in one of the holders 11. The slider 9AA is provided with a number of first lock elements 13A. The second mounting portion 9B comprises a number of second lock elements 13B—see FIG. 8—which are fixed to the rear cover 7 and are provided on the interior side 7A of the rear cover 7. In this embodiment the second lock elements 13B are integral parts of the rear cover 7 which is made from a plastic material, e.g. polycarbonate and acrylonitrile butadiene styrene polymer (PC/ABS). In this example the holders 11 as well as the sliders 9AA are made from a zinc-coated steel. Each holder 11 as well as each slider 9AA has the shape of an elongated body, which in the present embodiment is oriented with its longitudinal axis L in a vertical direction assuming the apparatus 1 is in its normal position. More particularly, the holders 11 are each located near a right flank 3R and a left flank 3L of the structure 3. The flanks 3R and 3L correspond to circumferential edge portions 7R and 7L, respectively, of the rear cover 7.

As the applied mounting devices 9 are equivalent, i.e. substantially the same or as in this example mirror images from each other, only one mounting device 9 will be discussed in detail. The same applies to the holders 11. For the sake of completeness it is noted that the applied mounting devices 9 and the applied holders 11 may be identical mounting devices and holders, respectively.

Particularly referring to FIG. 4 it is noted that the depicted holder 11 corresponds to the holder 11 situated near the right flank 3R considered according to the rear view in FIG. 3. The holder 11 is provided with bearing means, known per se, for guiding the slider 9AA over a limited distance along the longitudinal axis L. In the present embodiment such bearing means include glide faces between which the slider 9AA is movable in its axial direction. In the depicted example the slider 9AA has three locking elements 13A constituted as catch elements and created by bending tongues out of a main plane 19 of the slider 9AA. Various variants of such locking elements are possible, e.g. elements adhered to or screwed to the main plane 19. The number of locking elements 13A as well as the length of the slider 9AA depends among others on the dimensions of the rear cover 7.

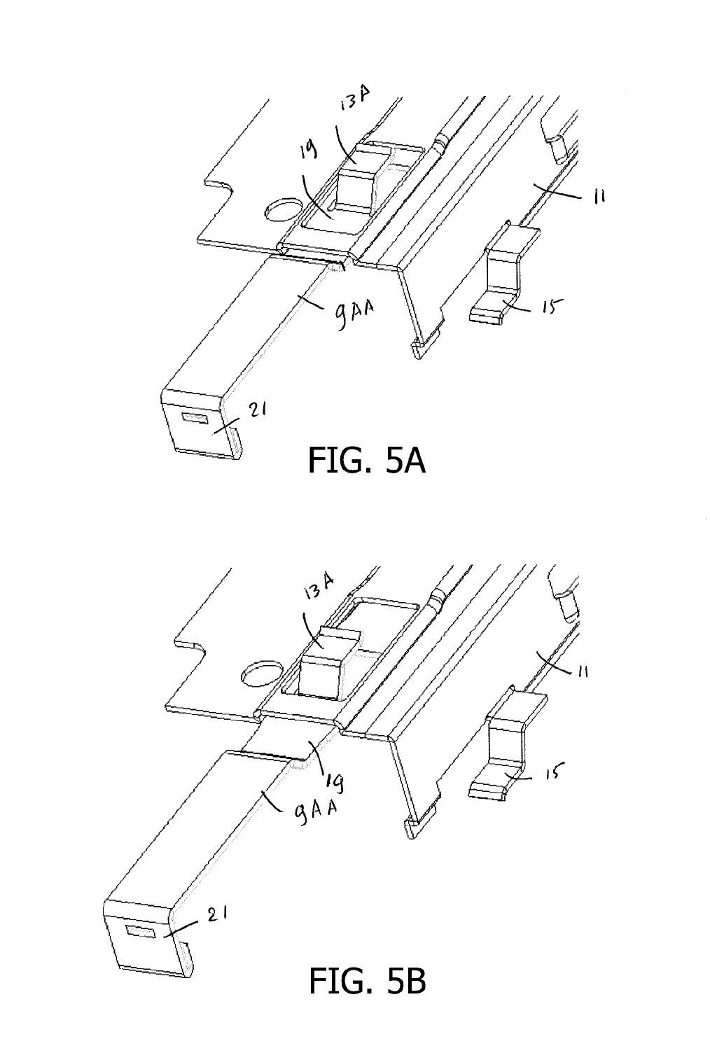

Particularly referring to FIGS. 5A and 5B it is noted that a part P1 of the assembly of the holder 11 and the slider 9AA as shown in FIG. 4 is depicted in these figures. In FIG. 5A the slider 9AA is in its lock position, while in FIG. 5B the slide 9AA is in its unlock position. The slider 9AA is movable between the lock position and the unlock position. The slider 9AA is provided with a control element 21 for controlling its axial movements between the lock position and the unlock position. The control element 21 has the function of a hand grip in order to facilitate the actuation of the slider 9AA.

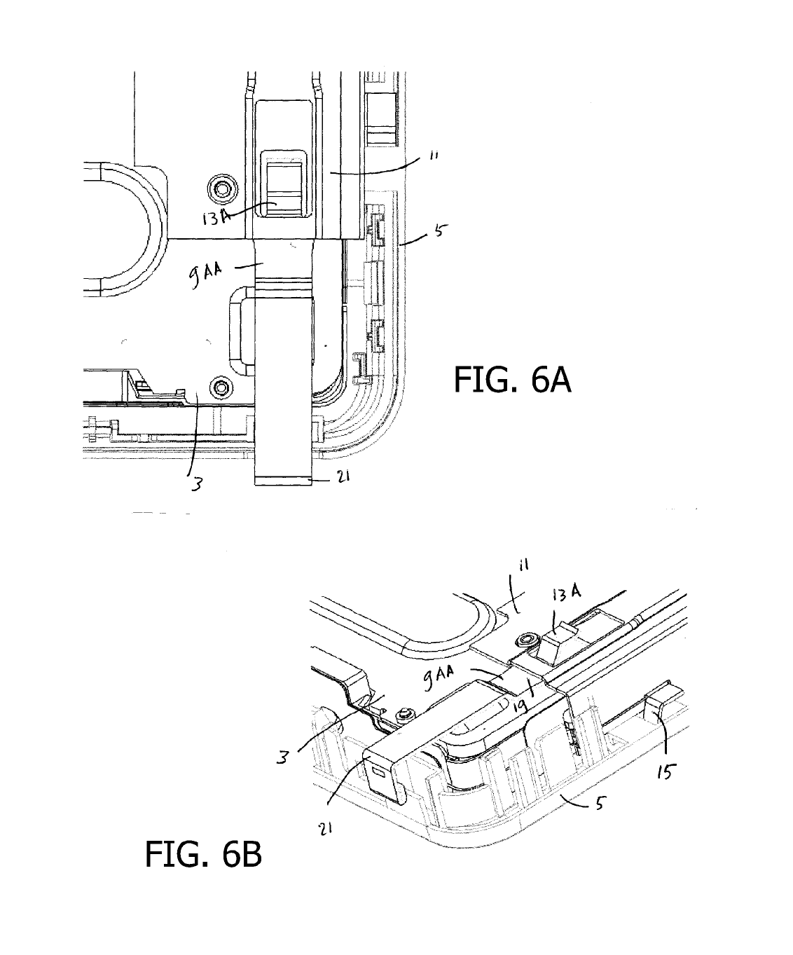

Particularly referring to FIGS. 6A and 6B it is noted that a part P2 of the apparatus 1 as shown in FIG. 2 is depicted in these figures. In FIG. 2, and thus also in the FIGS. 6A and 6B the slider 9AA is in its unlock position.

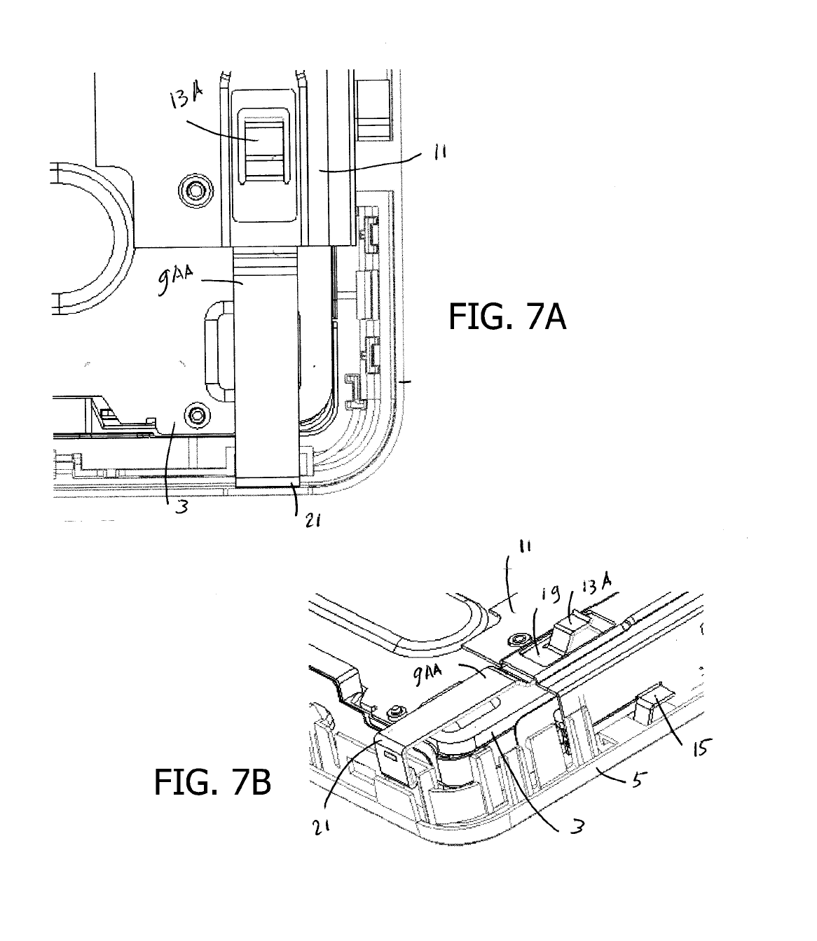

Particularly referring to FIGS. 7A and 7B it is noted that a part P3 of the apparatus 1 as shown in FIG. 3 is depicted in these figures. In FIG. 3, and thus also in the FIGS. 7A and 7B the slider 9AA is in its lock position.

Particularly referring to FIGS. 8 and 9 it is noted that a part P4 of the rear cover 7 as shown in FIG. 8 is depicted in FIG. 9. The rear cover 7 is on its interior side 7A provided with six second lock elements 13B, viz. three second lock elements 13B near its right circumferential edge portion 7R and three second lock elements 13B near its left circumferential edge portion 7L. The number of second lock elements 13B corresponds to the number of first lock elements 13A. Moreover the positions of the second lock elements 13B correspond to the positions of first lock elements 13A. In the present embodiment the second embodiments 13B are constituted as hook-shaped elements.

In the entirely assembled state of the apparatus 1—i.e. the state as disclosed in FIG. 1, but in a normal perspective view—the second lock elements 13B of the rear cover 7 are grasped and retained by the first lock elements 13A of the sliders 9AA, being in their lock positions. In this way the rear cover 7 is clamped against the front cover 5 constituting the housing 5, 7 with a hardly visible seam between the front cover 5 and the rear cover 7 and without any visible mounting means. In this context it is noted that the mounting device 9 is substantially situated between the structure 3 and the rear cover 7.

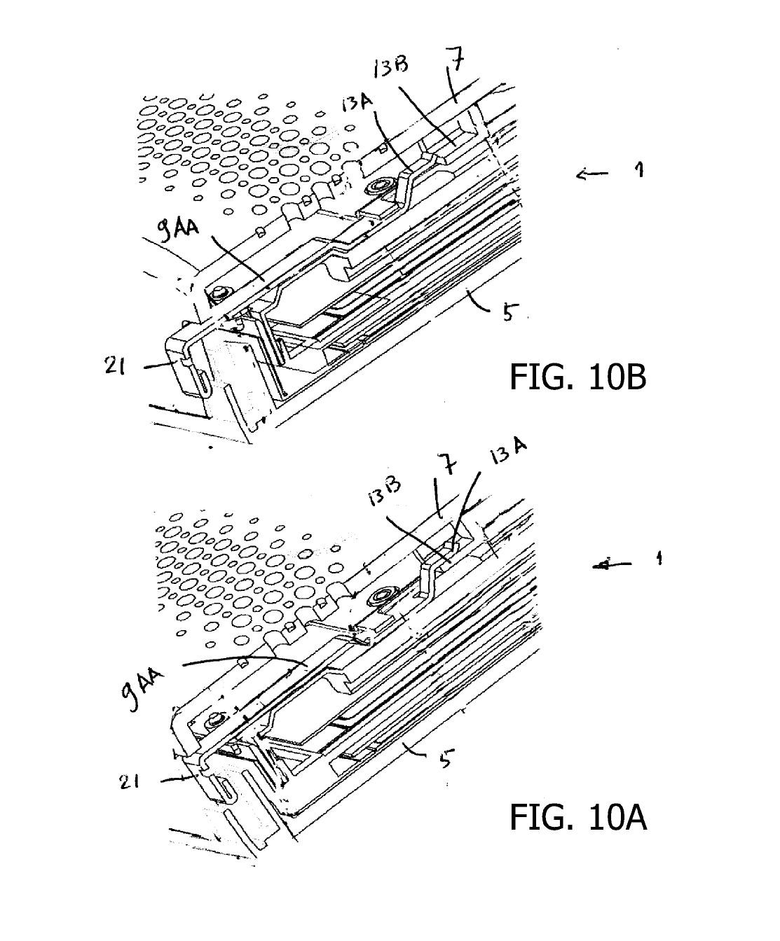

During the lifetime of the apparatus 1 it may be necessary to remove the rear cover 7 from its assembled position for e.g. service purposes. FIG. 10A shows a part of the entirely assembled apparatus 1 according to part P5 indicated in FIG. 1, wherein the sliders 9AA are in their lock positions and second locking elements 13B of the rear cover 7 are retained by the first locking elements 13A of the sliders 9AA. By tiring the control elements 21 out of the apparatus 1, the sliders 9AA together with the first lock elements 13A move from their lock positions to their unlock positions, thereby releasing the second lock elements 13B. FIG. 10B shows a part of the apparatus 1 according to part P5 indicated in FIG. 1, wherein the sliders 9AA are in their unlock positions and second locking elements 13B of the rear cover 7 are released by the first locking elements 13A of the sliders 9AA. In the situation as depicted in FIG. 10B the rear cover 7 can be taken away from the front panel 5, thereby exposing the structure 3, as is shown in the FIGS. 2 and 3.

A step in mounting the rear cover 7 on the assembly of structure 3 and front cover 5 includes bringing the rear cover 7 into the right position with respect to the structure 3 and the front cover 5, i.e. the position wherein the second lock elements 13B are facing the first lock elements 13A of the sliders 9AA being in their unlock positions. In a next step the sliders 9AA are moved to their lock positions, by pushing the control elements 21 towards the apparatus 1, resulting in grasping and locking the second lock elements 13B by the first lock elements 13A. The first and second lock elements 13A, 13B engaged in this way result in the entirely assembled apparatus 1.

Summarizing, the invention relates to an electronic apparatus, more particular a flat-panel display apparatus, which is provided with a structure and a cover for at least partially covering the structure. The apparatus is further provided with a mounting device for detachably mounting the cover to the structure, wherein both attaching the cover and detaching the cover takes place in an easy way. The mounting device comprises a first mounting portion and a second mounting portion, which portions are constituted for mutual cooperation. One of the mounting portions is connected to the structure and the other mounting portion is connected to the cover. The second mounting portion is stationarily arranged and the first mounting portion is movably, arranged between a lock position and an unlock position. The first mounting portion is preferably provided with a carrier, preferably a slideably arranged carrier having first lock elements for cooperation with second lock elements of the second mounting portion. In the lock position the first and second mounting portions are engaged for retaining the cover in its mounting position. In the unlock position the first and second mounting portions are released.

It will be clear to a person skilled in the art that the scope of the present invention is not limited to the examples discussed in the foregoing. Several amendments and modifications of said examples are possible without deviating from the scope of the present invention as defined in the attached claims. While the present invention has been illustrated and described in detail in the figures and the description, such illustration and description are to be considered illustrative or exemplary only, and not restrictive. The present invention is not limited to the disclosed embodiments. Other variations to the disclosed embodiments can be understood and effected by a person skilled in the art in practicing the claimed invention, from a study of the figures, the description and the attached claims. In an example of such a variant the first mounting portion is a longitudinal carrier rotatably beared in the holder in order to be able to rotate around its length axis for locking and unlocking purposes. In the claims, the word “comprise” and conjugations thereof do not exclude other steps or elements, and the indefinite article “a” or “an” docs not exclude a plurality. The mere fact that certain measures are recited in mutually different dependent claims does not indicate that a combination of these measures cannot be used to advantage. Any reference signs in the claims should not be construed as limiting the scope of the present invention.

1. An electronic apparatus (1) provided with a structure (3), a cover (7) for at least partially covering the structure and a mounting device (9) for detachably mounting the cover to the structure, which mounting device comprises a first mounting portion (9a) and a second mounting portion (9B), which portions are constituted for mutual cooperation, wherein one of the mounting portions is connected to the structure and the other mounting portion is connected to the cover, wherein the second mounting portion is stationarily arranged and the first mounting portion is movably arranged with respect to the structure and the cover between a lock position and an unlock position, in which lock position the first and second mounting portions are engaged for retaining the cover in its mounting position, and in which unlock position the first and second mounting portions are released.

2. The electronic apparatus as claimed in claim 1, wherein the mounting device (9) is substantially situated between the structure (3) and the cover (7).

3. The electronic apparatus as claimed in claim 1, wherein the first mounting portion (9A) is slideably arranged.

4. The electronic apparatus as claimed in claim 1, wherein the mounting device (9) is provided with a holder (11) in which the first mounting portion (9A) is movably arranged.

5. The electronic apparatus as claimed in claim 1, wherein the first mounting portion (9A) is connected to the structure (3) and the second mounting portion (9B) is connected to the cover (7).

6. The electronic apparatus as claimed in claim 1, wherein the first mounting portion (9A) is provided with a carrier (19) provided with at least two first lock elements (13A) and the second mounting portion (9B) is provided with at least two second lock elements (13B), wherein the first and second lock elements 13A, 13B) are pairwisely interlocked in the lock position.

7. The electronic apparatus as claimed in claim 6, wherein the carrier (19) is provided with a control element (21) for controlling its movements.

8. The electronic apparatus as claimed in claim 6, wherein the first lock elements (13A0 and/or the second lock elements (13B) are constituted as catch elements.

9. The electronic apparatus as claimed in claim 6, wherein the carrier is a slider (19).

10. The electronic apparatus as claimed in claim 1, wherein at least two mounting devices (9) of the kind defined in claim 6 are provided, which mounting devices (9) are located at a distance from each other.

11. The electronic apparatus as claimed in claim 10, wherein the at least two mounting devices (9) each extends along a circumferential edge portion (7R, 7L) of the cover.

12. The electronic apparatus as claimed in claim 1, provided with a housing (5, 7), wherein the cover (7) is a part of the housing (5, 7).

13. The electronic apparatus as claimed in claim 12, wherein the housing (5, 7) is provided with a front portion (5) and a rear portion (7), wherein the rear portion is constituted by the cover.

14. The electronic apparatus as claimed in claim 1, being a flat-panel display apparatus (1).

15. A use of the electronic apparatus as claimed in claim 1.
